(19) United States
(12) Patent Application Publication
(10) Pub. No.: US 2024/0257764 A1
(43) Pub. Date: Aug. 1, 2024

(54) OPTICAL COMPENSATION SYSTEM AND OPTICAL COMPENSATING METHOD

(71) Applicant: LG Display Co., Ltd., Seoul (KR)

(72) Inventor: Jinhyuk KIM, Gyeongsangnam-do (KR)

(73) Assignee: LG Display Co., Ltd., Seoul (KR)

(21) Appl. No.: 18/425,945

(22) Filed: Jan. 29, 2024

(30) Foreign Application Priority Data
Jan. 31, 2023 (KR) 10-2023-0012694

(51) Int. Cl. G09G 3/3266; G01R 31/28; G09G 3/00

(52) U.S. Cl. CPC G09G 3/3266; G01R 31/2825; G09G 3/006; G09G 2300/0819; G09G 2300/0842; G09G 2310/06; G09G 2310/08; G09G 2320/0233; G09G 2320/0247; G09G 2330/12; G09G 2340/0435

(57) ABSTRACT

Embodiments of the disclosure relate to an optical compensation device and an optical compensation method that may minimize the flicker phenomenon by applying a polynomial regression algorithm. The optical compensation device may include a basic data sampling module for sampling a basic data of a subpixel disposed on a display panel; and a compensation data generating module for generating a compensation data for the subpixel by a polynomial regression method based on the sampled basic data.

### CROSS-REFERENCE TO RELATED APPLICATION

This application claims priority from Korean Patent Application No. 10-2023-0012694, filed on Jan. 31, 2023, which is hereby incorporated by reference for all purposes as if fully set forth herein.

### BACKGROUND

### Technical Field

Embodiments of the disclosure relate to an optical compensation device and an optical compensation method.

### Discussion of the Related Art

As the information society develops, demand for display devices in various forms for displaying images is increasing. Various types of display devices, such as liquid crystal display devices, plasma display panel displays, and organic light emitting display devices, are being utilized.

Among these display devices, the organic light emitting display device uses self-emissive organic light emitting diodes, providing advantages, such as a fast response and better contrast ratio, luminous efficiency, luminance, and viewing angle.

The organic light emitting display device may include organic light emitting diodes respectively arranged in a plurality of subpixels disposed on a display panel and cause each subpixel to emit light by controlling the driving current flowing to the organic light emitting diode to display images.

The image data supplied to the display device may be a still image or a video that is variable at a constant speed, such as a sports video, movie, or game video.

### SUMMARY

Accordingly, embodiments of the present disclosure are directed to an optical compensation device and an optical compensation method that substantially obviate one or more of the problems due to limitations and disadvantages of the related art.

An aspect of the present disclosure is to provide an optical compensation device and an optical compensation method that may quickly derive an optimal voltage value capable of minimizing the flicker phenomenon by applying a polynomial regression algorithm.

Another aspect of the present disclosure is to provide an optical compensation device and an optical compensation method that may minimize the flicker phenomenon by applying a polynomial regression algorithm.

Another aspect of the present disclosure is to provide an optical compensation device and an optical compensation method that may prevent leakage current from occurring by applying a polynomial regression algorithm.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, an optical compensation device may comprise a basic data sampling module for sampling a basic data of a subpixel disposed on a display panel and a compensation data generating module for generating a compensation data for the subpixel by a polynomial regression method based on the sampled basic data.

In another aspect, an optical compensation method may comprise sampling a basic data of a subpixel disposed on a display panel and generating a compensation data for the subpixel by a polynomial regression method based on the sampled basic data.

According to embodiments of the disclosure, there may be provided an optical compensation device and an optical compensation method that may quickly derive an optimal voltage value capable of minimizing the flicker phenomenon by applying a polynomial regression algorithm.

According to embodiments of the disclosure, there may be provided an optical compensation device and an optical compensation method that may minimize the flicker phenomenon by applying a polynomial regression algorithm.

According to embodiments of the disclosure, there may be provided an optical compensation device and an optical compensation method that may prevent leakage current from occurring by applying a polynomial regression algorithm.

According to embodiments of the disclosure, there may be provided an optical compensation device and an optical compensation method that may minimize the flicker phenomenon and prevent leakage current by applying a polynomial regression algorithm, allowing for low power consumption.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view schematically illustrating a system configuration of a display device according to embodiments of the disclosure;

FIG. 2 is a view illustrating a gate driving circuit disposed on a display panel of a display device according to embodiments of the disclosure;

FIG. 3 is a view illustrating an equivalent circuit of a subpixel of a display device according to embodiments of the disclosure;

FIGS. 4 and 5 are diagrams illustrating a driving timing of a subpixel of a display device according to embodiments of the disclosure;

FIG. 6 is a cross-sectional view illustrating a display panel of a display device according to embodiments of the disclosure;

FIG. 7 is a cross-sectional view illustrating a display panel of a display device according to embodiments of the disclosure;

FIG. 8 is a block diagram illustrating an optical compensation device according to embodiments of the disclosure;

FIG. 9 is a view illustrating an example algorithm applied to an optical compensation device according to embodiments of the disclosure;

FIG. 10 is a view illustrating another example algorithm applied to an optical compensation device according to embodiments of the disclosure; and

FIG. 11 is a flowchart illustrating an optical compensation method according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

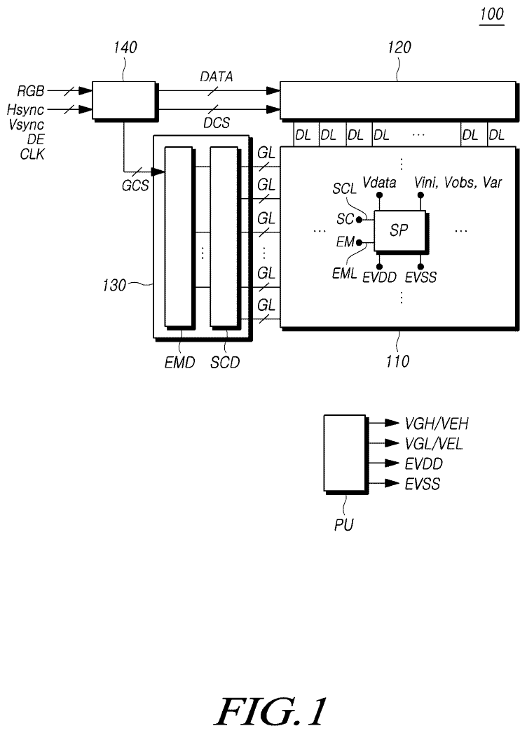

FIG. 1 is a view illustrating a system configuration of a display device 100 according to embodiments of the disclosure.

Referring to FIG. 1, the display device 100 may include a display panel 110 including a plurality of subpixels SP, a gate driving circuit 130 for supplying a gate signal to each of the plurality of subpixels SP, a data driving circuit 120 for supplying a data signal to each of the plurality of subpixels SP, a controller 140 for controlling the gate driving circuit 130 and the data driving circuit 120, and a power circuit PU for supplying power required for driving to each of the plurality of subpixels SP.

The display panel 110 may include a display area DA where the subpixel SP is positioned and a non-display area NDA disposed to surround the display area DA and where the gate driving circuit 130 and the data driving circuit 120 are disposed.

In the display panel 110, a plurality of gate lines GL and a plurality of data lines DL cross each other. Each of the plurality of subpixels SP is connected to the gate line GL and the data line DL. Specifically, one subpixel SP receives a gate signal SC and EML from the gate driving circuit 130 through the gate line GL, receives a data signal Vdata from the data driving circuit 120 through the data line DL, and receives a driving voltage EVDD and a base voltage EVSS from the power circuit PU.

Here, the gate line GL may supply the scan signal SC and the emission control signal EM to the corresponding subpixel SP, and the data line DL may supply the data voltage Vdata to the corresponding subpixel SP. Further, according to various embodiments, the gate line GL may include a plurality of scan lines SCL for supplying the scan signal SC to the corresponding subpixel SP and an emission control signal line EML for supplying the emission control signal EM to the corresponding subpixel SP. Further, the plurality of subpixels SP may further include a power line VL to receive a bias voltage Vobs and initialization voltages Var and Vini.

Further, each of the subpixels SP includes a light emitting element ED and a pixel circuit (also referred to as a pixel driving circuit) that controls driving of the light emitting element ED. The pixel circuit may include a plurality of switching elements, driving elements, and capacitors. The switching element and the driving element may be composed of thin film transistors. In the pixel circuit, the driving element controls the amount of current supplied to the light emitting element ED according to the data voltage, thereby adjusting the amount of light emitted from the light emitting element ED. The plurality of switching elements receive the scan signals SC supplied through the plurality of scan lines SCL and the emission control signal EM supplied through the emission control line EML, operating the pixel circuit.

For example, the display panel 110 may be implemented as a non-transmissive display panel or a transmissive display panel. The transmissive display panel may be applied to a transparent display device in which an image is displayed on the screen and a real object in the background is visible. The display panel 110 may be formed of a flexible display panel. For example, the flexible display panel may be implemented as an organic light emitting diode OLED panel using a plastic substrate.

Each of the subpixels SP may be divided into a red pixel, a green pixel, and a blue pixel for color implementation. Each of the subpixels SP may further include a white pixel.

Touch sensors may be disposed on the display panel 110. The touch input may be sensed by separate touch sensors or sensed through the subpixels SP. Touch sensors may be configured outside the display panel 110 or may be embedded inside the display panel 110.

The controller 140 processes image data RGB input from the outside to suit the size and resolution of the display panel 110 and supplies the data to the data driving circuit 120. The controller 140 may generate a gate control signal GCS and a data control signal DCS using synchronizing signals input from the outside, e.g., a clock signal CLK, a data enable signal DE, a horizontal synchronization signal Hsync, and a vertical synchronization signal Vsync. The controller 140 may control the gate driving circuit 130 and the data driving circuit 120 by supplying the gate control signal GCS and the data control signal DCS to the gate driving circuit 130 and the data driving circuit 120, respectively.

The controller 140 may be configured to be integrated with various processors, e.g., a microprocessor, a mobile processor, an application processor, etc., depending on a device to be mounted thereon.

The host system may be any one of a television (TV) system, a set-top box, a navigation system, a personal computer (PC), a home theater system, a mobile device, a wearable device, and a vehicle system.

The controller 140 multiplies the input frame frequency by i (where, i is a positive integer larger than 0) to control the operation timing of the display driving circuit (e.g., data driving circuit or gate driving circuit) at a frame frequency of input frame frequency×i Hz. The input frame frequency is 60 Hz in the national television standards committee (NTSC) scheme and 50 Hz in the phase-alternating line (PAL) scheme.

The controller 140 generates signals so that the subpixels SP may be driven at various refresh rates. In other words, the controller 140 generates driving-related signals such that the subpixel SP is driven at a variable refresh rate (VRR) mode or to be switchable between a first refresh rate and a second refresh rate. For example, the controller 140 may simply change the speed of the clock signal, generate a synchronization signal to create a horizontal blank or vertical blank, or drive the gate driving circuit 130 in a mask scheme, driving the subpixel SP at various refresh rates.

The controller 140 generates a gate control signal GCS for controlling the operation timing of the gate driving circuit 130 and a data control signal DSC for controlling the operation timing of the data driving circuit 120 based on the timing signals Vsync, Hsync, and DE received from the host system. The controller 140 controls the operation timing of the display driving circuit to synchronize the gate driving circuit 130 and the data driving circuit 120.

The voltage level of the gate control signal GCS output from the controller 140 may be converted into gate-on voltages VGL and VEL and gate-off voltages VGH and VEH through a level shifter (not shown) and be supplied to the gate driving circuit 130. The level shifter converts the low level voltage of the gate control signal GCS into a gate low voltage VGL and converts the high level voltage of the gate control signal GCS to the gate high voltage VGH. The gate control signal GCS includes a start pulse and a shift clock.

The gate driving circuit 130 supplies the scan signal SC to the gate line GL according to the gate control signal GCS supplied from the controller 140. The gate driving circuit 130 may be disposed on one side or two opposite sides of the display panel 110 in a gate in panel (GIP) type.

The gate driving circuit 130 sequentially outputs gate signals to the plurality of gate lines GL under the control of the controller 140. The gate driving circuit 130 may sequentially supply the gate signals to the gate lines GL by shifting the gate signals using the shift register.

The gate signal may include a scan signal (SC) and an emission control signal (EM) in an organic light emitting display device. The scan signal SC may include a scan pulse swinging between a gate-on voltage VGL and a gate-off voltage VGH. The emission control signal EM may include an emission control signal pulse that swings between a gate-on voltage VEL and a gate-off voltage VEH.

The scan pulse is synchronized with the data voltage Vdata to select subpixels SP of the line where data is to be written. The emission control signal EM defines the emission times of the subpixels SP.

The gate driving circuit 130 may include an emission control circuit EMD and at least one scan driving circuit SCD.

The emission control circuit EMD outputs an emission control signal pulse in response to a start pulse and a shift clock from the controller 140 and sequentially shifts the emission control signal pulse according to the shift clock.

At least one scan driving circuit SCD may output a scan pulse in response to the start pulse and the shift clock from the controller 140 and shifts the scan pulse according to the shift clock timing.

The data driving circuit 120 may convert the image data RGB into the data voltage Vdata according to the data control signal DCS supplied from the controller 140 and supplies the converted data voltage Vdata to the subpixel SP through the data line DL.

Although it is illustrated in FIG. 1 that one data driving circuit 120 is disposed on one side of the display panel 110, the number and location of the data driving circuits 120 are not limited thereto.

In other words, the data driving circuit 120 may be composed of a plurality of integrated circuits (ICs) and may be divided into a plurality of units and disposed on one side of the display panel 110.

The power circuit PU generates DC power necessary for driving the pixel array of the display panel 110 and the display driving circuit by means of a DC-DC converter. The DC-DC converter may include a charge pump, a regulator, a buck converter, a boost converter, and the like. The power circuit PU receives a DC input voltage applied from a host system (not shown) and generates DC voltages, such as gate-on voltages VGL and VEL, gate-off voltages VGH and VEH, a driving voltage EVDD, and a base voltage EVSS. The gate-on voltages VGL and VEL and gate-off voltages VGH and VEH are supplied to a level shifter (not shown) and the gate driving circuit 130. The driving voltage EVDD and base voltage EVSS are commonly supplied to the subpixels SP.

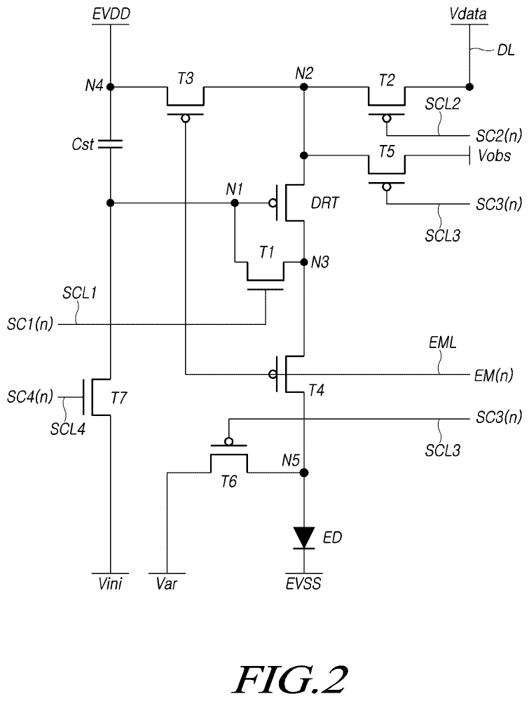

FIG. 2 is a view illustrating an equivalent circuit of a subpixel of a display device 100 according to embodiments of the disclosure.

FIG. 2 merely illustrates a pixel circuit as an example for description, and embodiments of the disclosure are not limited as long as it has a structure that may control light emission of the light emitting element ED by applying a light emission signal EM(n). For example, the pixel circuit may include an additional scan signal, a switching thin film transistor connected to the additional scan signal, and a switching thin film transistor to which an additional initialization voltage is applied, and the connection relationship of the switching elements and connection positions of the capacitors may be varied. Hereinafter, for convenience of description, a display device 100 having the pixel circuit structure of FIG. 2 is described.

Referring to FIG. 2, each of the plurality of subpixels SP may include a pixel circuit having a driving transistor DRT and a light emitting element ED connected to the pixel circuit.

Referring to FIG. 2, each of the plurality of subpixels SP may be connected to a data line DL supplying a data voltage Vdata, a first scan line SCL1 supplying a first scan signal SC1(n), a second scan line SCL2 supplying a second scan signal SC2(n), a third scan line SCL3 supplying a third scan signal SC3(n), a fourth scan line SCL4 supplying a fourth scan signal SC4(n), and an emission control signal line EML supplying an emission control signal EM(n).

Referring to FIG. 2, the pixel circuit may drive the light emitting element ED by controlling a driving current flowing through the light emitting element ED. The pixel circuit may include a driving transistor DRT, first to seventh transistors T1 to T7, and a capacitor Cst. Each of the transistors DRT, T1 to T7 may include a first electrode, a second electrode, and a gate electrode. One of the first electrode and the second electrode may be a source electrode, and the other of the first electrode and the second electrode may be a drain electrode.

Each of the transistors DRT, T1 to T7 may be a P-type thin film transistor or an N-type thin film transistor. In the embodiment of FIG. 2, the first transistor T1 and the seventh transistor T7 are N-type thin film transistors, and the other transistors DRT, T2 to T6 are P-type thin film transistors. However, the disclosure is not limited thereto, and according to an embodiment, all or some of the transistors DRT, T1 to T7 may be P-type thin film transistors or N-type thin film transistors. The N-type thin film transistor may be an oxide thin film transistor (or a polycrystalline silicon thin film transistor), and the P-type thin film transistor may be a polycrystalline silicon thin film transistor (or an oxide thin film transistor).

Described below is an example in which the first transistor T1 and the seventh transistor T7 are N-type thin film transistors, and the other transistors DRT, T2 to T6 are P-type thin film transistors. Accordingly, the first transistor T1 and the seventh transistor T7 are turned on by applying a high-level voltage to the gate node, and the other transistors DRT, T2 to T6 are turned on by applying a low-level voltage to the gate node.

According to an embodiment, the first transistor T1 may function as a compensation transistor, the second transistor T2 may function as a data supply transistor, the third and fourth transistors T3 and T4 may function as emission control transistors, the fifth transistor T5 may function as a bias transistor, and the sixth and seventh transistors T6 and T7 may function as initialization transistors.

The light emitting element ED may include an anode electrode (or a pixel electrode) and a cathode electrode. The anode electrode of the light emitting element ED may be connected to the fifth node N5, and the cathode electrode may be connected to the base voltage EVSS.

The driving transistor DRT may include a first electrode connected to the second node N2, a second electrode connected to the third node N3, and a gate electrode connected to the first node N1. The driving transistor DRT may provide the driving current Id to the light emitting element ED based on the voltage of the first node N1 (or the data voltage stored in the capacitor Cst to be described below).

The first transistor T1 may include a first electrode connected to the first node N1, a second electrode connected to the third node N3, and a gate electrode receiving the first scan signal SC1(n). The first transistor T1 may be turned on in response to the first scan signal SC1(n). As the first node N1 and the third node N3 are electrically connected to each other according to the turn-on of the first transistor T1, the driving transistor DRT has a diode connection state, so that the threshold voltage Vth of the driving transistor DRT may be sampled. In this sense, the first transistor T1 may be referred to as a compensation transistor.

The storage capacitor Cst may be connected or formed between the first node N1 and the fourth node N4. The storage capacitor Cst may store or maintain the driving voltage EVDD.

The second transistor T2 may include a first electrode to which the data voltage Vdata may be applied through the data line DL, a second electrode connected to the second node N2, and a gate electrode for receiving the second scan signal SC2(n).

The second transistor T2 may be turned on in response to the second scan signal SC2(n) to transfer the data voltage Vdata to the second node N2. In this sense, the second transistor T2 may be a data supply transistor.

The third transistor T3 and the fourth transistor T4 may be connected between the driving voltage EVDD and the light emitting element ED, and may form a current movement path through which the driving current Id generated by the driving transistor DRT moves. Here, the third transistor T3 and the fourth transistor T4 may also be referred to as a first emission control transistor and a second emission control transistor, respectively.

The third transistor T3 may include a first electrode connected to the fourth node N4 to allow the driving voltage EVDD to be applied thereto, a second electrode connected to the second node N2, and a gate electrode for receiving the emission control signal EM(n).

The fourth transistor T4 may include a first electrode connected to the third node N3, a second electrode connected to the fifth node N5, and a gate electrode receiving the emission control signal EM(n). Here, the fifth node N5 may electrically correspond to the anode electrode of the light emitting element ED.

The third and fourth transistors T3 and T4 may be simultaneously turned on in response to the emission control signal EM(n). The third and fourth transistors T3 and T4 may be turned on, so that the driving current Id may be provided to the light emitting element ED. The light emitting element ED may emit light with a luminance corresponding to the driving current Id.

The fifth transistor T5 may include a first electrode for receiving a bias voltage Vobs, a second electrode connected to the second node N2, and a gate electrode to which a third scan signal SC3(n) may be applied. The fifth transistor T5 may be a bias transistor.

The sixth transistor T6 may include a first electrode for receiving the first initialization voltage Var, a second electrode connected to the fifth node N5, and a gate electrode to which the third scan signal SC3(n) may be applied.

The sixth transistor T6 may be turned on in response to the third scan signal SC3(n) before the light emitting element ED emits light (or after the light emitting element ED emits light). Accordingly, the first initialization voltage Var may be applied to the fifth node N5, so that the anode electrode (or pixel electrode) of the light emitting element ED may be initialized. The light emitting element ED may have a parasitic capacitor formed between the anode electrode and the cathode electrode. While the light emitting element ED emits light, the parasitic capacitor is charged so that the anode electrode of the light emitting element ED may have a specific voltage. Accordingly, the amount of charge accumulated in the light emitting element ED may be initialized by applying the first initialization voltage Var to the anode electrode of the light emitting element ED through the sixth transistor T6.

In the disclosure, the gate electrodes of the fifth and sixth transistors T5 and T6 are configured to commonly receive the third scan signal SC3(n). However, the disclosure is not necessarily limited thereto, and the gate electrodes of the fifth and sixth transistors T5 and T6 may be configured to receive separate scan signals to be independently controlled.

The seventh transistor T7 may include a first electrode capable of receiving a second initialization voltage Vini, a second electrode connected to the first node N1, and a gate electrode receiving a fourth scan signal SC4(n).

The seventh transistor T7 may be turned on in response to the fourth scan signal SC4(n). Accordingly, the second initialization voltage Vini may be applied to the first node N1 corresponding to the gate electrode of the driving transistor DRT. Accordingly, the gate electrode of the driving transistor DRT may be initialized.

Unnecessary charge may remain in the gate electrode of the driving transistor DRT due to the driving voltage EVDD stored in the capacitor Cst. Accordingly, the remaining charge amount may be initialized by applying the second initialization voltage Vini to the gate electrode of the driving transistor DRT through the seventh transistor T7.

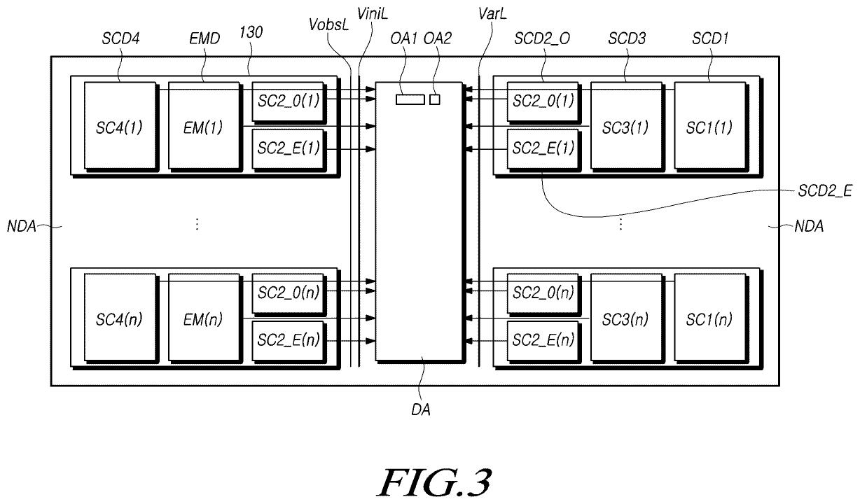

FIG. 3 is a view illustrating a gate driving circuit 130 disposed on a display panel 110 of a display device 100 according to embodiments of the disclosure.

Referring to FIG. 3, the gate driving circuit 130 includes an emission control circuit EMD and a scan driving circuit SCD.

The scan driving circuit SCD may include first to fourth scan driving circuits SCD1, SCD2_O/SCD2_E, SCD3, and SCD4 capable of supplying first to fourth scan signals SC1(n), SC2(n), SC3(n), and SC4(n).

Among the first to fourth scan driving circuits SCD1, SCD2_O/SCD2_E, SCD3, and SCD4, the second scan driving circuit SCD2 may include an odd-numbered second scan driving circuit SCD2_O and an even-numbered second scan driving circuit SCD2_E.

The gate driving circuit 130 may be configured on two opposite sides of the display area DA. In other words, the gate driving circuit 130 may include a first gate driving circuit 130 positioned on one side of the display area DA and a second gate driving circuit 130 positioned on the other side of the display area DA.

Each of the first gate driving circuit 130 and the second gate driving circuit 130 may include a plurality of stages STG(1) to STG(n).

Each of the plurality of stages STG(1) to STG(n) of the first gate driving circuit 130 may include a second scan driving circuit SCD2_O and SCD2_E, a fourth scan driving circuit SCD4, and an emission control circuit EMD. Each of the plurality of stages STG(1) to STG(n) of the second gate driving circuit 130 may include a first scan driving circuit SCD1, a second scan driving circuit SCD2_O and SCD2_E, and a third scan driving circuit SCD3. However, the disclosure is not limited thereto, and the emission control circuit EMD and the first to fourth scan driving circuits SCD1, SCD2_O/SCD2_E, SCD3, and SCD4 may be disposed differently.

In each of the plurality of stages STG(1) to STG(n), one of the plurality of first scan signals SC1(1) to SC1(n), one of the plurality of second scan signals SC2(1) to SC2(n), one of the plurality of third scan signals SC3(1) to SC3(n), one of the plurality of fourth scan signals SC4(1) to SC4(n), and one of the plurality of emission control signals EM(1) to EM(n) may be output to one of the plurality of subpixel rows.

The plurality of first scan signals SC1(1) to SC1(n) may be respectively applied to the plurality of first scan lines SCL1 disposed on the display panel 110. The plurality of second scan signals SC2(1) to SC2(n) may be respectively applied to the plurality of second scan lines SCL2 disposed on the display panel 110. The plurality of third scan signals SC3(1) to SC3(n) may be respectively applied to the plurality of third scan lines SCL3 disposed on the display panel 110. The plurality of fourth scan signals SC4(1) to SC4(n) may be respectively applied to the plurality of fourth scan lines SCL4 disposed on the display panel 110. The emission control signals EM(1) to EM(n) may be respectively applied to the emission control signal lines EML disposed on the display panel 110.

The first scan signals SC1(1) to SC1(n) may be used as signals for driving the first transistor T1 (compensation transistor) included in each pixel circuit. The second scan signals SC2(1) to SC2(n) may be used as signals for driving the second transistor T2 (data supply transistor) included in each pixel circuit. The third scan signals SC3(1) to SC3(n) may be used as signals for driving the fifth and sixth transistors T5 and T6 (bias transistors) included in each pixel circuit. The fourth scan signals SC4(1) to SC4(n) may be used as signals for driving the seventh transistor T7 (initialization transistor) included in each pixel circuit. The emission control signals EM(1) to EM(n) may be used as signals for driving the third and fourth transistors T3 and T4 (emission control transistors) included in each pixel circuit. For example, when the emission control transistors of the subpixels SP are controlled using the emission control signals EM(1) to EM(n), the emission time of the light emitting element may be varied.

Referring to FIG. 3, a bias voltage bus line VobsL, a first initialization voltage bus line VarL, and a second initialization voltage bus line ViniL may be disposed between the gate driving circuit 130 and the display area DA.

The bias voltage bus line VobsL, the first initialization voltage bus line VarL, and the second initialization voltage bus line ViniL may supply the bias voltage Vobs, the first initialization voltage Var, and the second initialization voltage Vini, respectively, from the power circuit PU to the pixel circuit.

In the drawings, the bias voltage bus line VobsL, the second initialization voltage line VarL, the bus and second initialization voltage bus line ViniL are shown as being positioned on only one side of the left or right side of the display area DA but, without limitations thereto, may be positioned on two opposite sides or, even when positioned on one side, the position is not limited to the left or right side.

Referring to FIG. 3, one or more optical areas OA1 and OA2 may be disposed in the display area DA.

One or more optical areas OA1 and OA2 may be disposed to overlap one or more optical electronic devices, such as capture devices, such as cameras (image sensors) or detection sensors, such as proximity sensors and illuminance sensors, and the like.

The one or more optical areas OA1 and OA2 may have a transmittance higher than a certain level by forming a light transmission structure for the operation of the optical electronic device. In other words, the number of subpixels SP per unit area in the one or more optical areas OA1 and OA2 may be smaller than the number of subpixels SP per unit area in the normal area except for the optical areas OA1 and OA2 in the display area DA. In other words, the resolution of one or more optical areas OA1 and OA2 may be lower than that of the normal area in the display area DA.

The light transmission structure in one or more optical areas OA1 and OA2 may be formed by patterning a cathode electrode in a portion where the subpixel SP is not disposed. In this case, the patterned cathode electrode may be removed by a laser.

Alternatively, a cathode electrode may be selectively formed and patterned using a material, such as an anti-cathode deposition layer.

Further, the light transmission structure in one or more optical areas OA1 and OA2 may be formed by separating the light emitting element ED and the pixel circuit in the subpixel SP. In other words, the light emitting element ED of the subpixel SP may be positioned on the optical areas OA1 and OA2, and the plurality of transistors TFT constituting the pixel circuit may be disposed around the optical areas OA1 and OA2, so that the light emitting element ED may be electrically connected to the pixel circuit through the transparent metal layer.

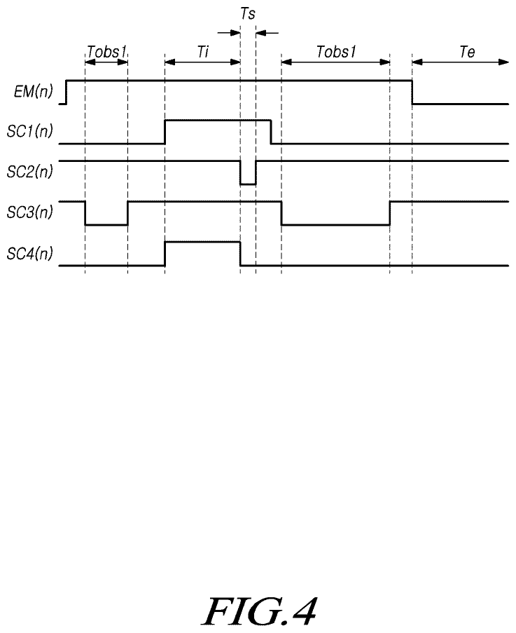

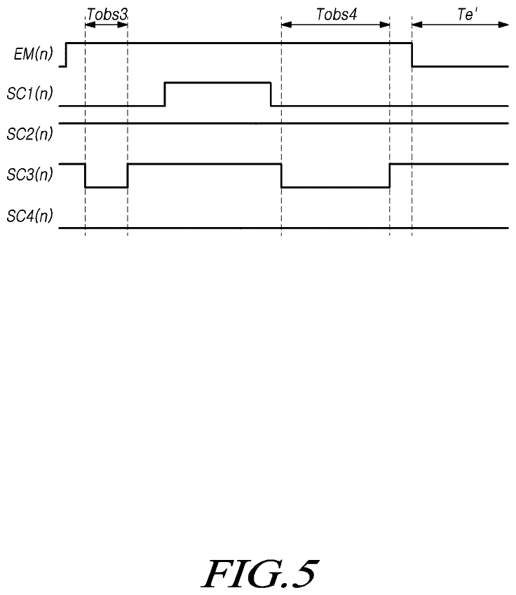

FIGS. 4 and 5 are diagrams illustrating a driving timing of a subpixel SP of a display device 100 according to embodiments of the disclosure. FIGS. 4 and 5 are views illustrating operations of a scan signal and an emission control signal in a refresh period and a hold period in the pixel circuit illustrated in FIG. 2.

The display device 100 according to an embodiment of the disclosure may operate in a variable refresh rate (VRR) mode. In the VRR mode, the display device 100 operates at a constant frequency and the pixel may be operated with the refresh rate at which the data voltage Vdata is updated increased at a time requiring fast driving, and the pixel may be operated with the refresh rate reduced at a time requiring slow driving or low power consumption.

Each of the plurality of subpixels SP may be driven through a combination of a refresh period and a hold period within 1 second. In the disclosure, one set is defined as repeating a combination of a refresh period when the data voltage Vdata is updated for one second and a hold period when the data voltage Vdata is not updated. One set period becomes a period when the combination of the refresh period and the hold period is repeated.

When the display device 100 is driven at the refresh rate of 120 Hz, the display device 100 may be driven only with a refresh period. In other words, the refresh period may be driven 120 times within 1 second. One refresh period is 1/120=8.33 ms, and one set period is also 8.33 ms.

When the display device 100 is driven at the refresh rate of 60 Hz, the refresh period and the hold period may be alternately driven. In other words, the refresh period and the hold period may be alternately driven 60 times each within 1 second. Each of one refresh period and one hold period is 0.5/60=8.33 ms, and one set period is 16.66 ms.

When the display device 100 is driven at the refresh rate of 1 Hz, one frame may be driven in one refresh period and 119 hold periods after one refresh period. When the display device 100 is driven at the refresh rate of 1 Hz, one frame may be driven in a plurality of refresh periods and a plurality of hold periods. In this case, each period of one refresh period and one hold period is 1/120=8.33 ms, and one set period is 1 s.

In the refresh period, a new data voltage Vdata is charged and the new data voltage Vdata is applied to the driving transistor DRT, whereas in the hold period, the data voltage Vdata of the previous frame is maintained and used. Meanwhile, the hold period is also referred to as a skip period in the sense that a process of applying a new data voltage Vdata to the driving transistor DRT is omitted.

Each of the plurality of subpixels SP may initialize the voltage charged or remaining in the pixel circuit during the refresh period. Specifically, each of the plurality of subpixels SP may remove the influence of the data voltage Vdata and the driving voltage EVDD stored in the previous frame during the refresh period. Accordingly, each of the plurality of subpixels SP may display an image corresponding to the new data voltage Vdata in the hold period.

Each of the plurality of subpixels SP may display an image by providing a driving current corresponding to the data voltage Vdata to the light emitting element ED during the hold period, and may maintain the turned-on state of the light emitting element ED.

First, driving of the pixel circuit and the light emitting element during the refresh period of FIG. 4 is described. The refresh period may include at least one bias period Tobs1 and Tobs2, an initialization period T1, a sampling period Ts, and an emission period Te, but this is merely an embodiment and the disclosure is not necessarily limited to this order.

Referring to FIG. 4, the pixel circuit may operate including at least one bias period Tobs1 and Tobs2 during a refresh period.

The at least one bias period Tobs1 and Tobs2 is a period when an on-bias stress operation OBS where the bias voltage Vobs is applied is performed, the emission control signal EM(n) is a high voltage, and the third and fourth transistors T3 and T4 are turned off. The first scan signal SC1(n) and the fourth scan signal SC4(n) are low voltages, and the first transistor T1 and the seventh transistor T7 are turned off. The second scan signal SC2 is a high voltage, and the second transistor T2 is turned off.

The third scan signal SC3(n) is input as a low voltage, and the fifth and sixth transistors T5 and T6 are turned on. As the fifth transistor T5 is turned on, the bias voltage Vobs is applied to the first electrode of the driving transistor DRT connected to the second node N2.

Here, the bias voltage Vobs may be supplied to the third node N3, which is the drain electrode of the driving transistor DRT, thereby reducing the charging time or the charging delay of the voltage of the fifth node N5, which is the anode electrode of the light emitting element ED, during the emission period. The driving transistor DRT maintains a stronger saturation state.

For example, as the bias voltage Vobs increases, the voltage of the third node N3, which is the drain electrode of the driving transistor DRT, may increase, and the gate-source voltage or the drain-source voltage of the driving transistor DRT may decrease. Therefore, it is preferable that the bias voltage Vobs is greater than at least the data voltage Vdata.

In this case, the magnitude of the drain source current Id passing through the driving transistor DRT may be reduced, and the stress of the driving transistor DRT may be reduced in a positive bias stress situation, addressing the charging delay of the voltage of the third node N3. In other words, performing the on-bias stress operation OBS before sampling the threshold voltage Vth of the driving transistor DRT may alleviate hysteresis of the driving transistor DRT.

Accordingly, the on-bias stress operation OBS in the at least one bias period Tobs1 and Tobs2 may be defined as an operation of directly applying an appropriate bias voltage to the driving transistor DRT during non-emission periods.

Further, as the sixth transistor T6 is turned on in the at least one bias period Tobs1 and Tobs2, the anode electrode (or pixel electrode) of the light emitting element ED connected to the fifth node N5 is initialized to the first initialization voltage

### Var.

However, the gate electrodes of the fifth and sixth transistors T5 and T6 may be configured to receive separate scan signals to be independently controlled. In other words, it is not necessarily required to simultaneously apply the bias voltage to the first electrode of the driving transistor DRT and the anode electrode of the light emitting element ED in the bias period.

Referring to FIG. 4, the pixel circuit may operate including an initialization period T1 during a refresh period. The initialization period T1 is a period when the voltage of the gate electrode of the driving transistor DRT is initialized.

The first scan signal SC1(n) to the fourth scan signal SC4(n) and the emission control signal EM(n) are high voltages, and the first transistor T1 and the seventh transistor T7 are turned on. The second to sixth transistors T2, T3, T4, T5, and T6 are turned off. As the first and seventh transistors T1 and T7 are turned on, the gate electrode and the second electrode of the driving transistor DRT connected to the first node N1 are initialized to the second initialization voltage Vini.

Referring to FIG. 4, the pixel circuit may operate including a sampling period Ts during a refresh period. The sampling period is a period for sampling the threshold voltage Vth of the driving transistor DRT.

The first scan signal SC1(n), the third scan signal SC3(n), and the emission control signal EM(n) are high voltages, and the second scan signal SC2(n) and the fourth scan signal SC4(n) are low voltages. Accordingly, the third to seventh transistors T3, T4, T5, T6, and T7 are turned off, the first transistor T1 is maintained in the on state, and the second transistor T2 is turned on. In other words, the second transistor T2 may be turned on to apply the data voltage Vatat to the driving transistor DRT, and the first transistor T1 may be diode-connected between the first node N1 and the third node N3 to sample the threshold voltage Vth of the driving transistor DRT.

Referring to FIG. 4, the pixel circuit may operate including an emission period Te during a refresh period. The emission period Te is a period when the sampled threshold voltage Vth is offset and the light emitting element ED is rendered to emit light with a driving current corresponding to the sampled data voltage.

The emission control signal EM(n) is a low voltage, and the third and fourth transistors T3 and T4 are turned on.

As the third transistor T3 is turned on, the driving voltage EVDD connected to the fourth node N4 is applied to the first electrode of the driving transistor DRT connected to the second node N2 through the third transistor T3. The driving current Id supplied from the driving transistor DRT to the light emitting element ED via the fourth transistor T4 is independent of the value of the threshold voltage Vth of the driving transistor DRT, so that the threshold voltage Vth of the driving transistor DRT may be compensated for.

Next, driving of the pixel circuit and the light emitting element ED during the hold period is described with reference to FIG. 5.

The hold period may include at least one bias period Tobs3 and Tobs4 and an emission period Te′. An operation of the pixel circuit that is the same as the operation of the refresh period is omitted.

As described above, the refresh period differs from the hold period in that in the refresh period, a new data voltage Vdata is charged and the new data voltage Vdata is applied to the gate electrode of the driving transistor DRT whereas in the hold period, the data voltage Vdata of the refresh period is maintained and used. Therefore, unlike the refresh period, the hold period does not require the initialization period T1 and the sampling period Ts.

In the operation during the hold period, only one on-bias stress operation OBS may suffice. However, in this embodiment, to facilitate driving the circuit, the third scan signal SC3(n) of the hold period is driven in the same manner as the third scan signal SC3(n) of the refresh period, and accordingly, the on-bias stress operation OBS may be operated twice as in the refresh period.

The difference between the driving signal in the refresh period described with reference to FIG. 4 and the driving signal in the hold period in FIG. 5 lies in the second and fourth scan signals SC2(n) and SC4(n). Since the initialization period T1 and the sampling period Ts are unnecessary in the hold period, unlike in the refresh period, the second scan signal SC2(n) is always a high voltage, and the fourth scan signal SC4(n) is always a low voltage. In other words, the second and seventh transistors T2 and T7 are always turned off.

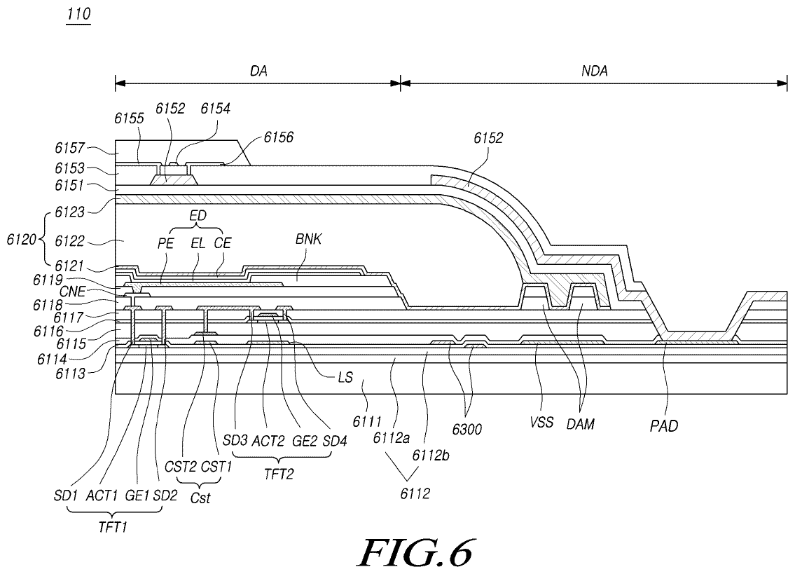

FIG. 6 is a cross-sectional view illustrating a display panel 110 of a display device 100 according to embodiments of the disclosure.

FIG. 6 is a cross-sectional view including two thin film transistors TFT1 and TFT2 and one capacitor Cst.

For example, the two thin film transistors TFT1 and TFT2 include a thin film transistor TFT1 including a polycrystalline semiconductor material and a thin film transistor TFT2 including an oxide semiconductor material. In this case, the thin film transistor including the polycrystalline semiconductor material is referred to as a polycrystalline thin film transistor, and the thin film transistor including the oxide semiconductor material is referred to as an oxide thin film transistor.

For example, the first active layer ACT1 of the first thin film transistor TFT1 of the two thin film transistors TFT1 and TFT2 may be positioned closer to the substrate 111 than the second active layer ACT2 of the second thin film transistor TFT2.

For example, the first thin film transistor TFT1 of the two thin film transistors TFT1 and TFT2 may be a polycrystalline thin film transistor, and the second thin film transistor TFT2 may be an oxide thin film transistor.

For example, the first thin film transistor TFT1 illustrated in FIG. 6 may be an emission switching thin film transistor connected to the light emitting element ED, and the second thin film transistor TFT2 may be any one switching thin film transistor connected to the capacitor Cst.

One subpixel SP may include a light emitting element ED and a pixel driving circuit for applying a driving current to the light emitting element ED.

The pixel driving circuit may be disposed on the substrate 6111. For example, the light emitting element ED may be disposed on the pixel driving circuit. An encapsulation layer 6120 may be disposed on the light emitting element ED. The encapsulation layer 6120 may protect the light emitting element ED from moisture or oxygen.

The pixel driving circuit may denote one subpixel array unit including a driving transistor, a switching transistor, and a capacitor. The light emitting element ED may denote an array unit including a pixel electrode PE, a common electrode CE, and a light emitting layer EL disposed between the pixel electrode PE and the common electrode CE.

For example, the driving transistor and at least one switching transistor may use an oxide semiconductor as an active layer. The thin film transistor using an oxide semiconductor material as an active layer may have an excellent leakage current blocking effect and is relatively inexpensive to manufacture as compared to the thin film transistor using a polycrystalline semiconductor material as an active layer. Therefore, to reduce power consumption and manufacturing costs, the pixel driving circuit according to an embodiment includes a driving transistor using an oxide semiconductor material and at least one switching transistor.

All of the thin film transistors constituting the pixel driving circuit may be implemented with an oxide semiconductor material while only thin film transistors corresponding to some switching transistors may implemented with an oxide semiconductor material.

As the thin film transistor using an oxide semiconductor material has difficulty in securing reliability while the thin film transistor using a polycrystalline semiconductor material has superior reliability and high operation speed, an embodiment may include both the switching thin film transistor using an oxide semiconductor material and the switching thin film transistor using a polycrystalline semiconductor material.

The substrate 6111 may be implemented in a multi-layer structure in which organic films and inorganic films are alternately stacked. For example, the substrate 6111 may be formed as organic films, such as polyimide, and inorganic films, such as silicon oxide (Siox), are alternately stacked.

A first buffer layer 6112 may be disposed on the substrate 6111.

The first buffer layer 6112 may include a lower buffer layer 6112a and an auxiliary buffer layer 6112b. The lower buffer layer 6112a is to block moisture that may penetrate from the outside, and may be formed by stacking multiple layers of silicon oxide (SiOx). The auxiliary buffer layer 6112b on the lower buffer layer 6112a may be a layer additionally disposed to protect the device from moisture permeation.

A first thin film transistor TFT1 is formed on the substrate 6111. The first thin film transistor TFT1 may use a polycrystalline semiconductor material as an active layer. The first thin film transistor TFT1 may include a first active layer ACT1 including a channel through which electrons or holes move, a first gate electrode GE1, a first source electrode SD1, and a first drain electrode SD2.

The first active layer ACT1 may include a first channel area and a first source area and a first drain area on two opposite sides of the first channel area.

The first source area and the first drain area may be areas which have been rendered conductive by doping an intrinsic polycrystalline semiconductor material with a predetermined concentration of group 5 or group 3 impurity ions, such as of phosphorus (P) or boron (B). The first channel area may maintain an intrinsic state of the polycrystalline semiconductor material and provide a path for electrons or holes to move.

Meanwhile, the first thin film transistor TFT1 may include a first gate electrode GE1 overlapping the first channel area of the first active layer ACT1. A first gate insulation layer 6113 may be disposed between the first gate electrode GEL and the first active layer ACT1. The first gate insulation layer 6113 may be formed of a single inorganic layer of, or a stack of multiple inorganic layers of silicon oxide (SiOx) film or a silicon nitride (SiNx). In an embodiment, the first thin film transistor TFT1 has a top gate structure where the first gate electrode GE1 is positioned above the first active layer ACT1. Accordingly, the first electrode CST1 included in the capacitor Cst and the light blocking layer LS included in the second thin film transistor TFT2 may be formed of the same material as the first gate electrode GE1. By forming the first gate electrode GE1, the first electrode CST1, and the light blocking layer LS through a single mask process, the number of mask processes may be reduced.

The first gate electrode GE1 is formed of a metal material. For example, the first gate electrode GE1 may be a single layer or a multi-layer structure formed of any one of, or an alloy of, molybdenum Mo, aluminum Al, chromium Cr, gold Au, titanium Ti, nickel Ni, neodymium Nd, and copper Cu, but is not limited thereto.

A first interlayer insulation layer 6114 is disposed on the first gate electrode GE1. The first interlayer insulation layer 6114 may be implemented of silicon oxide (Siox), silicon nitride (SiNx), or the like.

The display panel 110 may further include an upper buffer layer 6115, a second gate insulation layer 6116, and a second interlayer insulation layer 6117 sequentially disposed on the first interlayer insulation layer 6114, and the first thin film transistor TFT1 includes a first source electrode SD1 and a first drain electrode SD2 formed on the second interlayer insulation layer 6117 and connected with the first source area and the first drain area, respectively.

The first source electrode SD1 and the first drain electrode SD2 may be a single layer or a multi-layer structure formed of any one of, or an alloy of, molybdenum Mo, aluminum Al, chromium Cr, gold Au, titanium Ti, nickel Ni, neodymium Nd, and copper Cu, but is not limited thereto.

The upper buffer layer 6115 spaces the second active layer ACT2 of the second thin film transistor TFT2 formed of the oxide semiconductor material apart from the first active layer ACT1 formed of the polycrystalline semiconductor material, and provides a basis for forming the second active layer ACT2.

The second gate insulation layer 6116 covers the second active layer ACT2 of the second thin film transistor TFT2. Since the second gate insulation layer 6116 is formed on the second active layer ACT2 formed of an oxide semiconductor material, the second gate insulation layer 6116 is implemented as an inorganic film. For example, the second gate insulation layer 6116 may be formed of silicon oxide (Siox), silicon nitride (SiNx), or the like.

The second gate electrode GE2 is formed of a metal material. For example, the second gate electrode GE2 may be a single layer or a multi-layer structure formed of any one of, or an alloy of, molybdenum Mo, aluminum Al, chromium Cr, gold Au, titanium Ti, nickel Ni, neodymium Nd, and copper Cu, but is not limited thereto.

Meanwhile, the second thin film transistor TFT2 includes a second active layer ACT2 formed on the upper buffer layer 6115 and formed of an oxide semiconductor material, a second gate electrode GE2 disposed on the second gate insulation layer 6116, and a second source electrode SD3 and a second drain electrode SD4 disposed on the second interlayer insulation layer 6117.

The second active layer ACT2 is formed of an oxide semiconductor material and includes an intrinsic second channel area that is not doped with impurities, and a second source area and a second drain area that are doped with impurities to be rendered conductive.

The second thin film transistor TFT2 further includes a light blocking layer LS positioned under the upper buffer layer 6115 and overlapping the second active layer ACT2. The light blocking layer LS may block light incident on the second active layer ACT2 to ensure reliability of the second thin film transistor TFT2. The light blocking layer LS may be formed of the same material as the first gate electrode GE1 and may be formed on an upper surface of the first gate insulation layer 6113. The light blocking layer LS may be electrically connected to the second gate electrode GE2 to form a dual-gate.

The second source electrode SD3 and the second drain electrode SD4, along with the first source electrode SD1 and the first drain electrode SD2, may be simultaneously formed of the same material on the second interlayer insulation layer 6117 to reduce the number of mask processes.

Meanwhile, the capacitor Cst may be implemented by disposing the second electrode CST2 on the first interlayer insulation layer 6114 to overlap the first electrode CST1. The second electrode CST2 may be a single layer or a multi-layer structure formed of any one of, or an alloy of, molybdenum (Mo), aluminum (Al), chromium (Cr), gold (Au), titanium (Ti), nickel (Ni), neodymium (Nd), and copper (Cu).

The capacitor Cst stores the data voltage applied through the data line DL for a certain period of time and then provides it to the light emitting element ED. The capacitor Cst includes two electrodes opposing to each other and a dielectric disposed therebetween. A first interlayer insulation layer 6114 is positioned between the first electrode CST1 and the second electrode CST2.

The first electrode CST1 or the second electrode CST2 of the capacitor Cst may be electrically connected to the second source electrode SD3 or the second drain electrode SD4 of the second thin film transistor TFT2. However, the connection relationship of the capacitor Cst may be changed according to the pixel driving circuit without being limited thereto.

Meanwhile, a first planarization layer 6118 and a second planarization layer 6119 are sequentially disposed on the pixel driving circuit to planarize an upper end of the pixel driving circuit. The first planarization layer 6118 and the second planarization layer 6119 may be an organic film, such as polyimide or acrylic resin.

A light emitting element ED is formed on the second planarization layer 6119.

The light emitting element ED may include a pixel electrode PE, a common electrode CE, and a light emitting layer EL disposed between the pixel electrode PE and the common electrode CE. When implemented as a pixel driving circuit that commonly uses a low-potential voltage connected to the common electrode CE, the pixel electrode PE is disposed as a separate electrode for each subpixel. In the case of implementing a pixel driving circuit that commonly uses a high-potential voltage, the common electrode CE may be disposed as a separate electrode for each subpixel.

The light emitting element ED is electrically connected to the driving element through the intermediate electrode CNE disposed on the first planarization layer 6118. Specifically, the pixel electrode PE of the light emitting element ED and the first source electrode SD1 of the first thin film transistor TFT1 constituting the pixel driving circuit are connected to each other through the intermediate electrode CNE.

The pixel electrode PE is connected to the intermediate electrode CNE exposed through a contact hole penetrating the second planarization layer 6119. Further, the intermediate electrode CNE is connected to the first source electrode SD1 exposed through a contact hole penetrating the first planarization layer 6118.

The intermediate electrode CNE serves as a medium connecting the first source electrode SD1 and the pixel electrode PE. The intermediate electrode CNE may be formed of a conductive material, such as copper (Cu), silver (Ag), molybdenum (Mo), or titanium (Ti).

The pixel electrode PE may be formed in a multilayer structure including a transparent conductive film and an opaque conductive film having high reflection efficiency. The transparent conductive film may be formed of a material with a relatively high work function value, such as indium-tin-oxide (ITO) or indium-zinc-oxide (IZO), and the opaque conductive film may be formed of a single layer or a multilayer structure including aluminum (Al), silver (Ag), copper (Cu), lead (Pb), molybdenum (Mo), titanium (Ti) or an alloy thereof. For example, the pixel electrode PE may be formed of a structure in which a transparent conductive film, an opaque conductive film, and a transparent conductive film are sequentially stacked, or a structure in which a transparent conductive film and an opaque conductive film are sequentially stacked.

The light emitting layer EL is formed in the order of hole-related layer, organic light emitting layer, and electron-related layer, or its reverse order, on the pixel electrode PE.

The bank layer BNK may be a pixel defining film exposing the pixel electrode PE of each subpixel SP. The bank layer BNK may be formed of an opaque material (e.g., black) to prevent light interference between adjacent subpixels SP. In this case, the bank layer BNK includes a light blocking material formed of at least one of color pigments, organic black, and carbon. A spacer (not shown) may be further disposed on the bank layer BNK.

The common electrode CE faces the pixel electrode PE with the light emitting layer EL interposed therebetween and is formed on the top and side surfaces of the light emitting layer EL. The common electrode CE may be integrally formed over the entire display area DA. The common electrode CE may be formed of a transparent conductive layer, such as indium tin oxide (ITO) or indium zinc oxide (IZO) when applied to a top emission-type organic light emitting display device.

An encapsulation layer 6120 that suppresses moisture permeation may be further disposed on the common electrode CE.

The encapsulation layer 6120 may block penetration of external moisture or oxygen into the light emitting element ED which is vulnerable to external moisture or oxygen. To this end, the encapsulation layer 6120 may include at least one inorganic encapsulation layer and at least one organic encapsulation layer, but is not limited thereto. In the disclosure, a structure of the encapsulation layer 6120 in which the first encapsulation layer 6121, the second encapsulation layer 6122, and the third encapsulation layer 6123 are sequentially stacked is described as an example.

The first encapsulation layer 6121 is formed on a portion of the substrate 6111 on which the common electrode CE is formed. The third encapsulation layer 6123 may be formed on a portion of the substrate 6111 on which the second encapsulation layer 6122 is formed, and may be formed to, together with the first encapsulation layer 6121, surround the upper, lower, and side surfaces of the second encapsulation layer 6122. The first encapsulation layer 6121 and the third encapsulation layer 6123 may minimize or prevent penetration of external moisture or oxygen into the light emitting element ED. The first encapsulation layer 6121 and the third encapsulation layer 6123 may be formed of an inorganic insulation material capable of low-temperature deposition, such as, e.g., silicon nitride (SiNx), silicon oxide (Siox), silicon oxynitride (SiOxNy), or aluminum oxide (Al₂O₃). Since the first encapsulation layer 6121 and the third encapsulation layer 6123 are deposited in a low temperature atmosphere, a light emitting element ED vulnerable to a high temperature atmosphere may be prevented from damage during the deposition process of the first encapsulation layer 6121 and the third encapsulation layer 6123.

The second encapsulation layer 6122 serves as a buffer to relieve stress between the layers due to bending of the display device 610 and may flatten a step between the layers. The second encapsulation layer 6122 is formed of a non-photosensitive organic insulating material, such as acrylic resin, epoxy resin, phenolic resin, polyamide resin, polyimide resin, polyethylene or silicon oxycarbon (SiOC), or a photosensitive organic insulating material, such as photoacrylic, formed on a portion of the substrate 6111 on which the first encapsulation layer 6121 is formed, but is not limited thereto. When the second encapsulation layer 6122 is formed through an inkjet method, a dam DAM may be disposed to prevent the liquid second encapsulation layer 6122 from spreading to the edge of the substrate 6111. The dam DAM may be disposed closer to the edge of the substrate 6111 than the second encapsulation layer 6122. The dam DAM may prevent diffusion of the second encapsulation layer 6122 to the pad area where the conductive pad disposed on the outermost edge of the substrate 6111 is disposed.

The dam DAM is designed to prevent diffusion of the second encapsulation layer 6122, but when the second encapsulation layer 6122 is formed to exceed the height of the dam DAM during the process, the second encapsulation layer 6122 which is an organic layer may be exposed to the outside, so that, e.g., moisture may easily penetrate into the light emitting element. Therefore, to prevent this, at least 10 or more dams DAM may be repeatedly formed. The dam DAM may be disposed on the second interlayer insulation layer 6117 of the non-display area NDA.

Further, the dam DAM may be formed simultaneously with the first planarization layer 6118 and the second planarization layer 6119. When the first planarization layer 6118 is formed, the lower layer of the dam DAM may be formed together, and when the second planarization layer 6119 is formed, the upper layer of the dam DAM may be formed together, so that the lower layer and the upper layer of the dam DAM may be formed to be stacked in a dual structure.

Accordingly, the dam DAM may be formed of the same material as the first planarization layer 6118 and the second planarization layer 6119, but is not limited thereto.

The dam DAM may be formed to overlap the low-potential driving power line VSS. For example, the low-potential driving power line VSS may be formed on a lower layer of an area where the dam DAM is positioned in the non-display area NDA.

The gate driving pattern 6300 constituting the gate driving circuit 130 configured in the form of a low-potential driving power line VSS and a gate in panel (GIP) may be formed to surround the periphery of the display panel 110, and the low-potential driving power line VSS may be positioned outside the gate driving pattern 6300. Further, the low potential driving power line VSS may be connected to the common electrode CE to apply a common voltage. Although the gate driving pattern 6300 is simply represented in the plan and cross-sectional views, it may be configured using a thin film transistor having the same structure as the thin film transistor of the display area DA.

The low-potential driving power line VSS is disposed outside the gate driving pattern 6300. The low-potential driving power line VSS is disposed outside the gate driving pattern 6300 and surrounds the display area DA. For example, the low-potential driving power line VSS may be formed of the same material as the first gate electrode GE1, but is not limited thereto. The low-potential driving power line VSS may be formed of the same material as the second electrode CST2 or the first source and drain electrodes SD1 and SD2, but is not limited thereto.

Further, the low-potential driving power line VSS may be electrically connected to the common electrode CE. The low-potential driving power line VSS may supply the low-potential driving voltage EVSS to a plurality of subpixels SP in the display area DA.

A touch sensor layer may be disposed on the encapsulation layer 6120. In the touch sensor layer, the touch buffer film 6151 may be positioned between the touch sensor metal including the touch electrode connection lines 6152 and 6154 and the touch electrodes 6155 and 6156 and the common electrode CE of the light emitting element ED.

The touch buffer film 6151 may block off penetration, into the organic material-containing light emitting layer EL, of external moisture or the chemical (e.g., developer or etchant) used upon manufacturing the touch sensor metal disposed on the touch buffer film 6151. Thus, the touch buffer film 6151 may prevent damage to the light emitting layer EL vulnerable to chemicals or moisture.

The touch buffer film 6151 is formed of an organic insulation material with a low permittivity of 1 to 3 and formed at a low temperature which is not more than a predetermined temperature (e.g., 100° C.) to prevent damage to the light emitting layer EL containing the organic material vulnerable to high temperature. For example, the touch buffer film 6151 may be formed of an acrylic-based, epoxy-based, or siloxane-based material. The touch buffer film 6151 with planarizability, formed of an organic insulation material, may prevent fracture of the touch sensor metal formed on the touch buffer film 6151 and damage to the encapsulation layer 6120 due to a warping of the organic light emitting display device.

According to the mutual-capacitance-based touch sensor structure, the touch electrodes 6155 and 6156 may be disposed on the touch buffer film 6151, and the touch electrodes 6155 and 6156 may be disposed to cross each other.

The touch electrode connection lines 6152 and 6154 may electrically connect the touch electrodes 6155 and 6156 to each other. The touch electrode connection lines 6152 and 6154 and the touch electrodes 6155 and 6156 may be positioned on different layers with the touch insulation film 6153 interposed therebetween.

The touch electrode connection lines 6152 and 6154 may be disposed to overlap the bank layer 6165, preventing a lowering of the aperture ratio.

Meanwhile, in the touch electrodes 6155 and 6156, a part of the touch electrode connection line 6152 may pass through the upper portion and side surface of the encapsulation layer 6120 and be electrically connected with the touch driving circuit (not shown) through the touch pad PAD.

A part of the touch electrode connection line 6152 may receive a touch driving signal from the touch driving circuit and transfer it to the touch electrodes 6155 and 6156 and transfer the touch sensing signals from the touch electrodes 6155 and 6156 to the touch driving circuit.

A touch passivation film 6157 may be disposed on the touch electrodes 6155 and 6156. In the drawings, the touch passivation film 6157 is shown as being disposed only on the touch electrodes 6155 and 6156 but, without limitations thereto, the touch passivation film 6157 may extend to the front or rear of the dam DAM to be disposed on the touch electrode connection line 6152 as well.

A color filter (not shown) may be further disposed on the encapsulation layer 6120, and the color filter may be positioned on the touch sensor layer or be positioned between the encapsulation layer 6120 and the touch sensor layer.

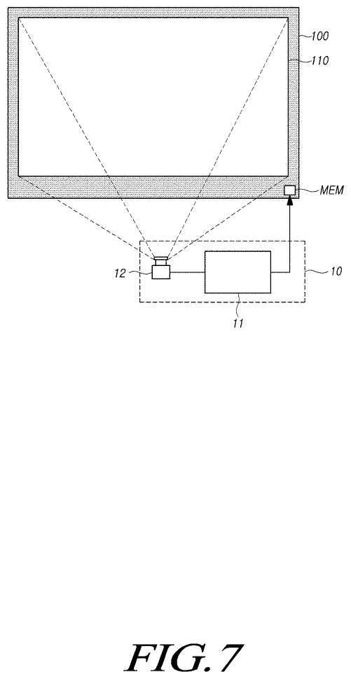

FIG. 7 illustrates an optical compensation system 10 according to embodiments of the disclosure.

Referring to FIG. 7, the optical compensation system 10 according to embodiments of the disclosure may perform the optical compensation function of generating compensation data for compensating for the image data to be suitable for the state of the display panel 110 so as to prevent screen glitch in the display panel 110 and storing the compensation data in the memory MEM of the display device 100.

Referring to FIG. 7, the optical compensation system 10 may include an optical compensation device 11 and a camera device 12.

The camera device 12 may photograph the image displayed on the display panel 110 of the display device 100 and output the photographed image to the optical compensation device 11. To distinguish the image displayed on the display panel 110 from the image photographed by the camera device 12, the image displayed on the display panel 110 is denoted as a display image, and the image photographed by the camera device 12 is denoted as a photographed image.

The optical compensation device 11 may obtain the photographed image from the camera device 12, generate compensation data based on the photographed image, and store the compensation data in the memory MEM of the display device 100.

The optical compensation device 11 may control the operation of at least one of the display device 100 and the camera device 12 to perform the optical compensation function. For example, the optical compensation device 11 may repeatedly display images of various grayscales on the display panel 110 for more accurate optical compensation processing.

The compensation data, generated by the optical compensation device 11 and stored in the memory MEM, may be used when driving the display device 100.

Referring to FIG. 7, the optical compensation device 11 and the camera device 12 included in the optical compensation system 10 according to embodiments of the disclosure may be configured as separate devices or may be integrated and configured as one device.

Referring to FIG. 7, in the optical compensation system 10 according to embodiments of the disclosure, the optical compensation device 11 and the display device 100 may be connected by a wired cable or via a wireless interface such as Bluetooth or wireless LAN, or may be connected via a wired or wireless network.

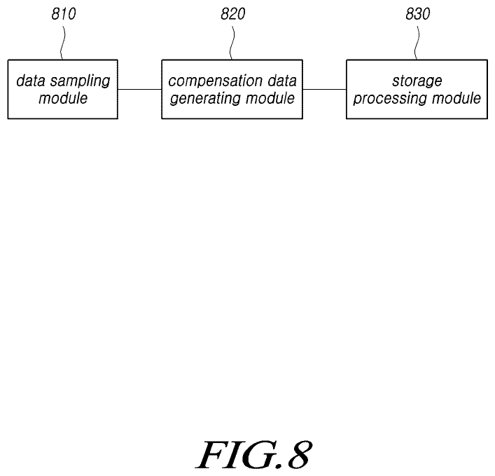

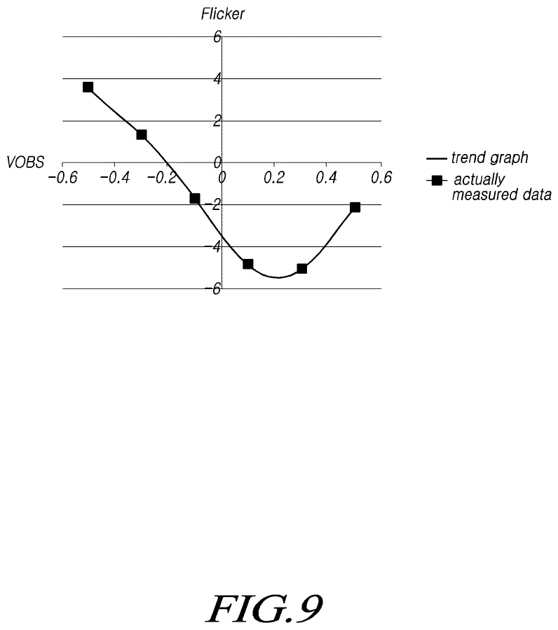

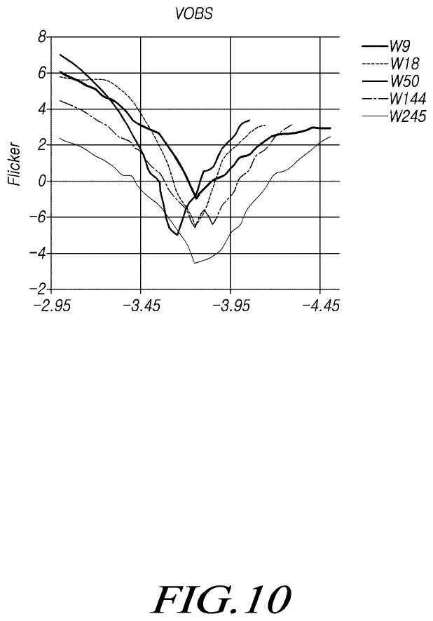

FIG. 8 is a block diagram illustrating an optical compensation device 11 according to embodiments of the disclosure. FIGS. 9 and 10 are views illustrating an example algorithm applied to an optical compensation device 11 according to embodiments of the disclosure.

Referring to FIG. 8, an optical compensation device 11 according to embodiments of the disclosure may comprise a basic data sampling module 810 for sampling a basic data of a subpixel disposed on a display panel and a compensation data generating module 820 generating compensation data for the subpixel by a polynomial regression method based on the sampled basic data.

The basic data may include a maximum voltage, a minimum voltage, a step voltage, and a flicker value at the step voltage.

Maximum voltage denotes the maximum value of input voltage. Minimum voltage denotes the minimum value of input voltage. The voltage range may be set to the range between the maximum voltage and the minimum voltage.

The step voltage denotes the voltage at which the actual flicker value is to be measured in order to derive a graph of a polynomial regression equation.

The flicker value represents the difference between the luminance waveform that appears in the refresh period and the luminance waveform that appears in the holding period as an index, and can be measured at each step voltage.

Referring to FIGS. 9 and 10, it may be identified that the step voltage and the flicker value at the step voltage in the basic data measured and sampled by the basic data sampling module 810 tend to have a V-shaped graph having minimum values.

Conventionally, the optimal voltage value at which the flicker value is minimized was derived simply by sequentially comparing the flicker values for all voltage values measured.

However, simply sequentially comparing the flicker values for all measured voltage values has the problems that the takt time increases and the takt time significantly increases as the measured range increases.

Referring to FIGS. 9 and 10, it is identified that the relationship between the step voltage and the flicker value tends to be in the form of a V-shaped graph, and an algorithm suitable for the relationship between the step voltage and the flicker value is developed.

Referring to FIG. 9, in the optical compensation device 11 according to embodiments of the disclosure, an optimal value of compensation data may be derived by a polynomial regression algorithm.

Specifically, the compensation data, which is the optimal value, may be a voltage value where the flicker value is minimized in the trend graph derived by the polynomial regression method based on the basic data.

Referring to FIG. 9, a trend graph may be derived by using a polynomial regression method based on six basic data which are actual measurement data. In this case, the data may be sampled by widening the interval between the step voltages of the basic data. For example, the trend graph may be expressed as a fifth-order polynomial as shown in equation (1) below. A polynomial may be expressed as the polynomial higher than fifth-order polynomial. And, the polynomial may be expressed as the polynomial lower than fifth-order polynomial.

$$F = {a}_{0} + {a}_{1} v + {a}_{2} {v}^{2} + {a}_{3} {v}^{3} + {a}_{4} {v}^{4} + {a}_{5} {v}^{5} \qquad ( 1 )$$

F is a flicker value, v is a step voltage, and a₀, a₁, a₂, a₃, a₄, and a₅ are coefficients.

In the trend graph derived by the polynomial regression method, the optimal step voltage at which the flicker value is minimized may be predicted. In this case, the interval between the step voltages derived by the trend graph may be set to be narrower than the interval between the step voltages of the basic data, and the flicker value at each step voltage may be derived.

Thereafter, an interval between the step voltages adjacent to the optimal step voltage value predicted in the trend graph is set equal to the interval between the step voltages derived in the trend graph. Actual flicker values of the step voltages adjacent to the optimal step voltage value predicted in the trend graph are measured. Compensation data, which is the optimal value, is derived by verifying whether the measured flicker value corresponding to the optimal step voltage value predicted in the trend graph becomes the minimum value.

Referring to FIGS. 4 and 5, the subpixel SP according to embodiments of the disclosure may be driven through a combination of a refresh period when a data voltage Vdata for driving the subpixel is applied to the display panel and a hold period for maintaining a voltage stored in a storage capacitor without applying the data voltage Vdata to the display panel.

In other words, in the refresh period, when the subpixel SP is driven, a new data voltage Vdata is charged and the new data voltage Vdata is applied to the driving transistor DRT, whereas in the hold period, the data voltage Vdata of the previous frame is maintained and used.

In the optical compensation device according to embodiments of the disclosure, a bias voltage Vobs may be applied to a driving transistor of the subpixel, and the bias voltage Vobs may be compensated by the compensation data.

In the refresh period and the hold period, the phenomenon in which a difference is caused between the on-bias state and the off-bias state of the characteristic of the current flowing between the drain electrode and source electrode of the driving transistor DRT by the voltage difference between the gate electrode and source electrode of the driving transistor DRT is referred to as hysteresis, which may cause ghosting. Further, the difference in the driving current flowing between the drain electrode and source electrode of the driving transistor DRT may not stabilize the driving characteristics of the light emitting element ED, but rather may cause a flicker which is a difference in luminance.

In the optical compensation device according to embodiments of the disclosure, the bias voltage Vobs may be compensation data where an optimal value is derived by a polynomial regression algorithm.

In other words, in the optical compensation device according to embodiments of the disclosure, the hysteresis and flicker phenomenon of the driving transistor DRT may be minimized by applying the bias voltage Vobs derived by the polynomial regression algorithm to the driving transistor DRT.

In the optical compensation device according to embodiments of the disclosure, the bias voltage Vobs may be applied to the driving transistor DRT during the refresh period or the hold period.

In the optical compensation device according to embodiments of the disclosure, when the subpixel SP is driven, a parking voltage Vpark may be applied to the subpixel, and the parking voltage Vpark may be compensated by the compensation data.

As described above, in the hold period, the data voltage Vdata of the previous frame is maintained and used as it is, and because no new data voltage Vdata is applied, the second transistor T2 (data supply transistor) supplying the data signal to the driving transistor maintains the off state for a long time.

A leakage current may be generated due to a potential difference between the source electrode and the drain electrode of the second transistor T2 (data supply transistor) while the second transistor T2 (data supply transistor) is maintained in an off state for a long time. The leakage current may vary the gate-source voltage difference of the driving transistor, and as a result, the driving current of the light emitting element may be varied during the hold period, causing image quality degradation.

During the hold period, the parking voltage Vpark may be applied from the power circuit PU to prevent leakage current from occurring in the second transistor T2 (data supply transistor) constituting the driving circuit of the subpixel, thereby preventing the driving current from being changed.

In the optical compensation device according to embodiments of the disclosure, the parking voltage Vpark may be applied to the second transistor T2 during the hold period.

When storing the compensation data in the memory MEM, the storage processing module 830 may compress and store the reference compensation data in a predetermined compression scheme. Here, the compression scheme may include at least one of a lossy compression scheme and a lossless compression scheme. For example, the compression scheme may vary depending on the type of data to be compressed in the compensation data and may vary depending on the type or specifications of the display device 100.

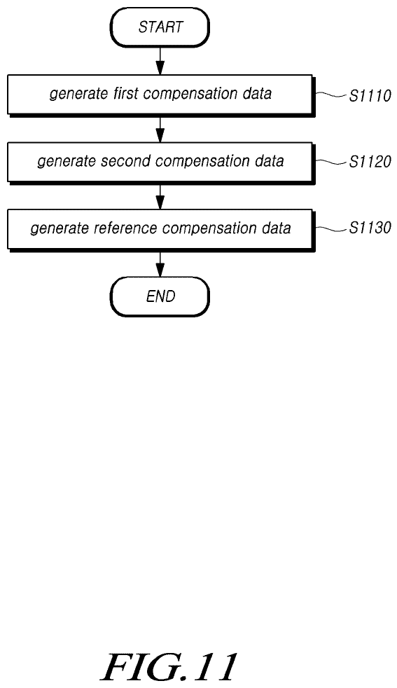

FIG. 11 is a flowchart illustrating an optical compensation method according to embodiments of the disclosure.

Referring to FIG. 11, an optical compensation method according to embodiments of the disclosure may comprise sampling (S1110) a basic data of a subpixel disposed on a display panel and generating (S1120) a compensation data for the subpixel by a polynomial regression method based on the sampled basic data.

The basic data may include a maximum voltage, a minimum voltage, a step voltage, and a flicker value at the step voltage.

Maximum voltage denotes the maximum value of input voltage. Minimum voltage denotes the minimum value of input voltage. The voltage range may be set to the range between the maximum voltage and the minimum voltage.

The step voltage denotes the voltage at which the actual flicker value is to be measured in order to derive a graph of a polynomial regression equation.

The flicker value represents the difference between the luminance waveform that appears in the refresh period and the luminance waveform that appears in the holding period as an index, and can be measured at each step voltage.

Referring to FIG. 11, in compensation data generation step S1220, an optimal value of the compensation data may be derived by a polynomial regression algorithm.

Specifically, the compensation data, which is the optimal value, may be a voltage value where the flicker value is minimized in the trend graph derived by the polynomial regression method based on the basic data.

For example, a trend graph may be derived by using a polynomial regression method based on basic data which are actual measurement data. In this case, the data may be sampled by widening the interval between the step voltages of the basic data.

For example, the trend graph may be expressed as a fifth-order polynomial as shown in equation (1) below. A polynomial may be expressed as the polynomial higher than fifth-order polynomial. And, the polynomial may be expressed as the polynomial lower than fifth-order polynomial.

$$F = {a}_{0} + {a}_{1} v + {a}_{2} {v}^{2} + {a}_{3} {v}^{3} + {a}_{4} {v}^{4} + {a}_{5} {v}^{5} \qquad ( 1 )$$

F is a flicker value, v is a step voltage, and a₀, a₁, a₂, a₃, a₄, and a₅ are coefficients.

In the trend graph derived by the polynomial regression method, the optimal step voltage at which the flicker value is minimized may be predicted. In this case, the interval between the step voltages derived by the trend graph may be set to be narrower than the interval between the step voltages of the basic data, and the flicker value at each step voltage may be derived.

Thereafter, an interval between the step voltages adjacent to the optimal step voltage value predicted in the trend graph is set equal to the interval between the step voltages derived in the trend graph. Actual flicker values of the step voltages adjacent to the optimal step voltage value predicted in the trend graph are measured. Compensation data, which is the optimal value, is derived by verifying whether the measured flicker value corresponding to the optimal step voltage value predicted in the trend graph becomes the minimum value.

In the optical compensation method according to embodiments of the disclosure, the subpixel SP may be driven through a combination of a refresh period when a data voltage Vdata for driving the subpixel is applied to the display panel and a hold period for maintaining a voltage stored in a storage capacitor without applying the data voltage Vdata to the display panel.

In other words, in the refresh period, a new data voltage Vdata is charged and the new data voltage Vdata is applied to the driving transistor DRT, whereas in the hold period, the data voltage Vdata of the previous frame is maintained and used.

In the optical compensation method according to embodiments of the disclosure, when the subpixel SP is driven, a bias voltage Vobs may be applied to a driving transistor of the subpixel, and the bias voltage Vobs may be compensated by the compensation data.

In the refresh period and the hold period, the phenomenon in which a difference is caused between the on-bias state and the off-bias state of the characteristic of the current flowing between the drain electrode and source electrode of the driving transistor DRT by the voltage difference between the gate electrode and source electrode of the driving t transistor DRT is referred to as hysteresis, which may cause ghosting. Further, the difference in the driving current flowing between the drain electrode and source electrode of the driving transistor DRT may not stabilize the driving characteristics of the light emitting element ED, but rather may cause a flicker which is a difference in luminance.

In the optical compensation method according to embodiments of the disclosure, the bias voltage Vobs may be compensation data where an optimal value is derived by a polynomial regression algorithm.

In other words, in the optical compensation method according to embodiments of the disclosure, the hysteresis and flicker phenomenon of the driving transistor DRT may be minimized by applying the bias voltage Vobs derived by the polynomial regression algorithm to the driving transistor DRT.

In the optical compensation method according to embodiments of the disclosure, the bias voltage Vobs may be applied to the driving transistor DRT during the refresh period or the hold period.

In the optical compensation method according to embodiments of the disclosure, when the subpixel SP is driven, a parking voltage Vpark may be applied to the subpixel, and the parking voltage Vpark may be compensated by the compensation data.

As described above, in the hold period, the data voltage Vdata of the previous frame is maintained and used as it is, and because no new data voltage Vdata is applied, the second transistor T2 (data supply transistor) supplying the data signal to the driving transistor maintains the off state for a long time.

A leakage current may be generated due to a potential difference between the source electrode and the drain electrode of the second transistor T2 (data supply transistor) while the second transistor T2 (data supply transistor) is maintained in an off state for a long time. The leakage current may vary the gate-source voltage difference of the driving transistor, and as a result, the driving current of the light emitting element may be varied during the hold period, causing image quality degradation.

During the hold period, the parking voltage Vpark may be applied from the power circuit PU to prevent leakage current from occurring in the second transistor T2 (data supply transistor) constituting the driving circuit of the subpixel, thereby preventing the driving current from being changed.

In the optical compensation method according to embodiments of the disclosure, the parking voltage Vpark may be applied to the second transistor T2 during the hold period.

Referring to FIG. 12, the optical compensation method according to embodiments of the disclosure may further include a compensation data storage step S1230. The compensation data storage step S1230 is a step of storing the compensation data in the memory MEM of the display device 100 including the display panel 110.

When storing the compensation data in the memory MEM in the compensation data storage step S1230, the compensation data may be compressed in a predetermined compression scheme. Here, the compression scheme may include at least one of a lossy compression scheme and a lossless compression scheme. For example, the compression scheme may vary depending on the type of data to be compressed in the compensation data and may vary depending on the type or specifications of the display device 100.

The foregoing embodiments are briefly described below.

An optical compensation device according to embodiments of the disclosure may comprise a basic data sampling module for a subpixel disposed on a display panel and a compensation data generating module generating compensation data for the subpixel by a polynomial regression method based on basic data.

In the optical compensation device according to embodiments of the disclosure, the basic data may include a maximum voltage, a minimum voltage, a step voltage, and a flicker value at the step voltage.

In the optical compensation device according to embodiments of the disclosure, the compensation data may be a voltage value at which the flicker value is minimized in a trend graph derived by the polynomial regression method based on the basic data.

The optical compensation device according to embodiments of the disclosure may include a refresh period when a data voltage for driving the subpixel is applied to the display panel and a hold period for maintaining a voltage stored in a storage capacitor without applying the data voltage to the display panel.

In the optical compensation device according to embodiments of the disclosure, a bias voltage may be applied to a driving transistor of the subpixel, and the bias voltage may be compensated by the compensation data.

In the optical compensation device according to embodiments of the disclosure, the bias voltage may be applied during the refresh period or the hold period.

In the optical compensation device according to embodiments of the disclosure, a parking voltage may be applied to the subpixel, and the parking voltage may be compensated by the compensation data.

In the optical compensation device according to embodiments of the disclosure, the parking voltage may be applied during the hold period.

An optical compensation method according to embodiments of the disclosure may comprise sampling basic data for a subpixel disposed on a display panel and generating compensation data for the subpixel by a polynomial regression method based on the basic data.

In the optical compensation method according to embodiments of the disclosure, the basic data may include a maximum voltage, a minimum voltage, a step voltage, and a flicker value at the step voltage.

In the optical compensation method according to embodiments of the disclosure, the compensation data may be a voltage value at which the flicker value is minimized in a trend graph derived by the polynomial regression method based on the basic data.

The optical compensation method according to embodiments of the disclosure may include a refresh period when a data voltage for driving the subpixel is applied to the display panel and a hold period for maintaining a voltage stored in a storage capacitor without applying the data voltage to the display panel.

In the optical compensation method according to embodiments of the disclosure, a bias voltage may be applied to a driving transistor of the subpixel, and the bias voltage may be compensated by the compensation data.

In the optical compensation method according to embodiments of the disclosure, the bias voltage may be applied during the refresh period or the hold period.

In the optical compensation method according to embodiments of the disclosure, a parking voltage may be applied to the subpixel, and the parking voltage may be compensated by the compensation data.

In the optical compensation method according to embodiments of the disclosure, the parking voltage may be applied during the hold period.

According to embodiments of the disclosure described above, there may be provided an optical compensation device and an optical compensation method that may quickly derive an optimal voltage value capable of minimizing the flicker phenomenon by applying a polynomial regression algorithm.

According to embodiments of the disclosure, there may be provided an optical compensation device and an optical compensation method that may minimize the flicker phenomenon by applying a polynomial regression algorithm.

According to embodiments of the disclosure, there may be provided an optical compensation device and an optical compensation method that may prevent leakage current from occurring by applying a polynomial regression algorithm.

According to embodiments of the disclosure, there may be provided an optical compensation device and an optical compensation method that may minimize the flicker phenomenon and prevent leakage current by applying a polynomial regression algorithm, allowing for low power consumption.

It will be apparent to those skilled in the art that various modifications and variations can be made in the optical compensation device and the optical compensation method of the present disclosure without departing from the technical idea or scope of the disclosure. Thus, it is intended that the present disclosure cover the modifications and variations of this disclosure provided they come within the scope of the appended claims and their equivalents.

What is claimed is:

1. An optical compensation device, comprising:
a basic data sampling module for sampling a basic data of a subpixel disposed on a display panel; and
a compensation data generating module for generating compensation data for the subpixel by a polynomial regression method based on the sampled basic data.

2. The optical compensation device of claim 1, wherein the basic data includes a maximum voltage, a minimum voltage, a step voltage, and a flicker value at the step voltage.

3. The optical compensation device of claim 2, wherein the compensation data is a voltage value at which the flicker value is minimized in a trend graph derived by the polynomial regression method based on the sampled basic data.

4. The optical compensation device of claim 1, wherein the optical compensation device includes:
a refresh period when a data voltage for driving the subpixel is applied to the display panel; and
a hold period for maintaining a voltage stored in a storage capacitor without applying the data voltage to the display panel.

5. The optical compensation device of claim 4, wherein when the subpixel is driven, a bias voltage is applied to a driving transistor of the subpixel, and wherein the bias voltage is compensated by the compensation data.

6. The optical compensation device of claim 5, wherein the bias voltage is applied during the refresh period or the hold period.

7. The optical compensation device of claim 4, wherein when the subpixel is driven, a parking voltage is applied to a data supply transistor of the subpixel, and wherein the parking voltage is compensated by the compensation data.

8. The optical compensation device of claim 7, wherein the parking voltage is applied during the hold period.

9. An optical compensation method, comprising:
sampling a basic data of a subpixel disposed on a display panel; and
generating a compensation data for the subpixel by a polynomial regression method based on the sampled basic data.

10. The optical compensation method of claim 9, wherein the basic data includes a maximum voltage, a minimum voltage, a step voltage, and a flicker value at the step voltage.

11. The optical compensation method of claim 10, wherein the compensation data is a voltage value at which the flicker value is minimized in a trend graph derived by the polynomial regression method based on the sampled basic data.

12. The optical compensation method of claim 9, wherein the optical compensation method includes:
a refresh period when a data voltage for driving the subpixel is applied to the display panel; and
a hold period for maintaining a voltage stored in a storage capacitor without applying the data voltage to the display panel.

13. The optical compensation method of claim 12, wherein when the subpixel is driven, a bias voltage is applied to a driving transistor of the subpixel, and wherein the bias voltage is compensated by the compensation data.

14. The optical compensation method of claim 13, wherein the bias voltage is applied during the refresh period or the hold period.

15. The optical compensation method of claim 12, wherein when the subpixel is driven, a parking voltage is applied to a data supply transistor of the subpixel, and wherein the parking voltage is compensated by the compensation data.

16. The optical compensation method of claim 15, wherein the parking voltage is applied during the hold period.
